(19) United States
(12) Patent Application Publication
(10) Pub. No.: US 2016/0289819 A1
(43) Pub. Date: Oct. 6, 2016

(54) HYDROXIDE FACILITATED OPTICAL FILMS

(71) Applicant: Veeco Instruments, Inc., Plainview, NY (US)

(72) Inventors: Ove Lyngnes, Fort Collins, CO (US); Binyamin Rubin, Smithtown, NY (US)

(21) Appl. No.: 14/677,699

(22) Filed: Apr. 2, 2015

(51) Int. Cl. C23C 14/34

(52) U.S. Cl. CPC C23C 14/3442; C23C 14/3414

(57) ABSTRACT

Methods of lowering the absorption losses of optical coatings at wavelengths shorter than 350 nm. During a deposition process of a metal oxide optical coating, dissociated hydroxide ion is added to the deposition process. The hydroxide ion source can be, for example, water vapor. By adding the hydroxide ion, a decrease in impurities and defects/dislocations in the optical coating is achieved.

### BACKGROUND

Oxide-based (e.g., SiO₂, Al₂O₃, HfO₂, ZrO₂, etc.) optical thin films are used in the fabrication of optical coatings, as an example for ultraviolet (UV) and vacuum ultraviolet (VUV) antireflection (AR) coatings. These AR coatings may be produced by depositing layers of thin film materials with alternating high and low indices of refraction on an optical substrate. Typically, the optical film layers are deposited by electron beam (e-beam) evaporation or ion beam assisted deposition (IBAD) evaporation. However, in other implementations, the optical film layers may be deposited using sputter deposition, such as ion beam sputtering or dual ion beam sputtering, or magnetron sputter deposition.

When compared to e-beam evaporation, thin films produced with ion beam sputter deposition may have a higher degree of material packing density, less granularity in morphology, and higher surface smoothness. As such, the optical performance of thin films deposited by ion beam sputtering may exhibit less optical losses than thin films produced by e-beam evaporation methods. Moreover, the denser optical films produced by ion beam sputter deposition may be more environmentally stable and have higher endurance in optical applications.

Even with sputter deposition, absorption loss is often encountered with the thin films. It is a challenge to reduce absorption losses, particularly at low wavelengths, such as less than 400 nm.

### SUMMARY

Implementations described and claimed herein address the foregoing problems by providing methods for lowering the absorption losses of oxide optical coatings at wavelengths shorter than 400 nm, or shorter than 350 nm. The methods include introducing a source of hydroxide ions (OH−) during the deposition process. By adding the hydroxide ion, a decrease in impurities and defects/dislocations in the optical coating is achieved.

One particular implementation of this disclosure is a method comprising depositing an ion beam sputtered metal oxide coating on a substrate in the presence of dissociated hydroxide ion.

Another particular implementation is a method of forming an optical coating, the method comprising depositing a metal oxide coating on a substrate in the presence of dissociated hydroxide ion.

For any of the methods, the dissociated hydroxide ion can be provided by water vapor introduced during the deposition process.

Other implementations are also described and recited herein.

### BRIEF DESCRIPTIONS OF THE DRAWING

FIG. 1 is a schematic diagram of an example hydroxide assisted ion beam sputter deposition system.

FIG. 2 is a schematic diagram of an example implementation of a hydroxide assisted ion beam sputter deposition system.

FIG. 3 is a schematic side view of a beam steering grid assembly for an ion beam sputter deposition system.

FIG. 4 is a graphical representation of transmission of a single layer silicon dioxide optical film on a fused silica substrate.

FIG. 5 is a graphical representation of transmission of a single layer alumina optical film on a fused silica substrate.

FIG. 6 is a flow chart of an example method for assisting the deposition of oxide-based optical thin films using hydroxide ion.

### DETAILED DESCRIPTION

In ion beam sputtered deposition systems, a beam of ions from an ion source strikes a target with such kinetic energy to sputter atoms of a desired material off from the target into a plume, which can subsequently deposit these atoms of desired material on a substrate.

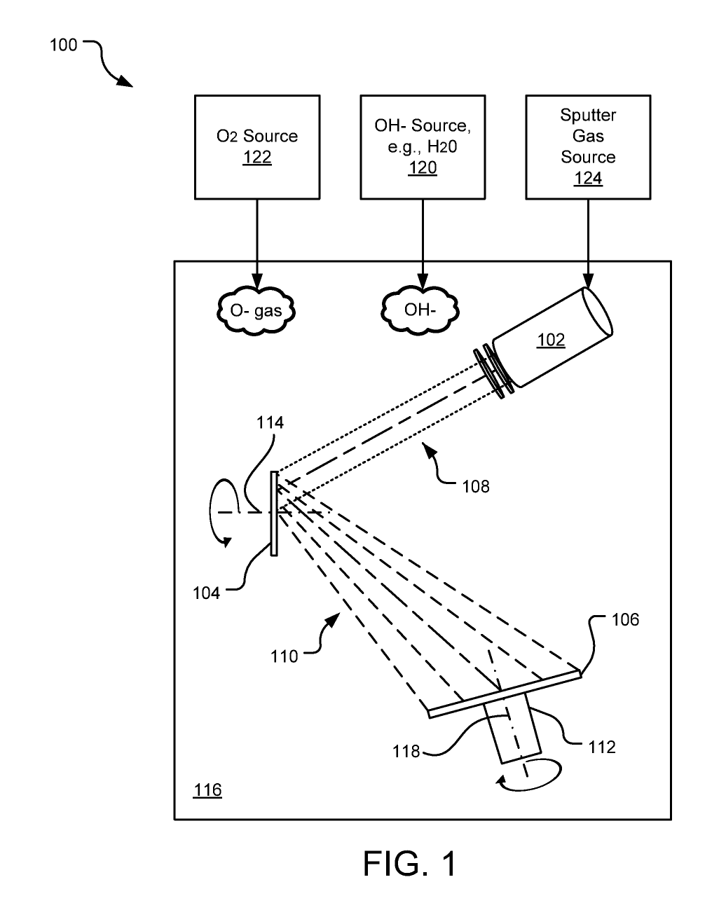

FIG. 1 illustrates a block diagram of an example hydroxide assisted ion beam sputter deposition system 100. Even though the implementation of the ion sputter system 100 is implemented as an ion beam sputter deposition system, the presently disclosed technology may also apply to other types of sputter deposition systems and/or e-beam evaporation systems that are used to produce oxide-based optical films (e.g., SiO₂, Al₂O₃, HfO₂, ZrO₂, Sc₂O₃, Y₂O₃, Ta₂O₅, TiO₂, Nb₂O₅, Yb₂O₃). The presently disclosed technology may be used to produce optical films that are low-loss in the UV and VUV ranges. The presently disclosed technology may also apply to optical coatings that provide low-loss properties in other wavelength ranges.

In the illustrated implementation, an ion sputter system 100 includes an ion source 102, a target assembly 104, and a substrate assembly 106 within an enclosure 116. The ion source 102 generates an ion beam 108 targeted or directed toward the target assembly 104. The ion source 102 may be a DC type, a radio frequency (RF) type or a microwave type gridded ion source, for example. Ion sputter gas (typically an inert gas such as Ar, Kr, or Xe) may be provided to the ion source 102 via a sputter gas source 124. Specifically, the ion sputter gas is injected into the ion source 102 where it is first ionized by a gas discharge or plasma. The ions within the ion source 102 are then accelerated by a set of ion beam grid optics at the output of the ion source 102 to form the ion beam 108.

The target assembly 104 may be rotated or moved in a desired manner, including rotation of the target assembly 104 about its axis 114 or pivoting the target assembly 104 to tilt the target assembly 104 to alter its angle with respect to the ion beam 108. The ion beam 108, upon striking the target assembly 104, generates a sputter plume 110 of material from one or more individual targets (not shown) affixed to the target assembly 104.

In one implementation of the ion sputter system 100, the one or more targets affixed to the target assembly 104 are made of a single material or of different materials that may be placed and interchanged on the target assembly 104. The different target materials (e.g., various metals, metalloids, metal-oxides and/or metalloid-oxides) allow layers of different materials to be deposited on the substrate(s) on the substrate assembly 106 to create multi-layer coatings. Examples of such materials to be deposited on the substrates include without limitation metal-oxides and metalloid-oxides (e.g., SiO₂, Al₂O₃, HfO₂, ZrO₂, Sc₂O₃, Y₂O₃, Ta₂O₅, TiO₂, Nb₂O₅, Yb₂O₃.).

The ion beam 108 strikes the target assembly 104 at such an angle that the sputter plume 110 generated from the target assembly 104 travels towards the substrate assembly 106. In one implementation of the ion sputter system 100, the sputter plume 110 is divergent as it travels towards the substrate assembly 106 and may partially overspray the substrate assembly 106. In another implementation, the sputter plume 110 may be made more or less concentrated so that its resulting deposition of material is directed over a particular area of the substrate assembly 106.

The substrate assembly 106 may be a single large substrate or a sub-assembly holder that holds multiple smaller individual substrates (not shown). In one example implementation of the ion sputter system 100, the substrate assembly 106 is attached to a fixture 112 that allows the substrate assembly 106 to be rotated or moved in a desired manner, including rotation of the substrate assembly 106 about its axis 118 or pivoting the fixture 112 to tilt the substrate assembly 106 to alter its angle with respect to the sputter plume 110.

The substrate(s) may be substantially planar (e.g., wafers and optical lenses or flats) or have various 3-D features (e.g., cubic (or faceted) optical crystals, curved optical lenses, and cutting tool inserts). In addition, the substrate(s) may be masked with mechanical templates or patterned etch resist layers (e.g., photo-resist) to help facilitate selected patterning of deposited films over the surface areas of the substrate(s).

The enclosure 116 is a controlled gaseous environment within which the ion deposition system 100 operates at a vacuum or near-vacuum conditions; pump(s) are provided in the system 100 to maintain the desired atmospheric conditions.

Having a vacuum or near-vacuum within the enclosure 116 may yield oxide-based deposited film(s) with too much absorption for a desired ultraviolet optical thin-film coating application, particularly at low wavelengths; that, too much transmission through the thin-film coating is lost due to absorption; this is also referred to as “absorption loss” and variations thereof. The absorption loss may be attributed to a stoichiometric reduction of oxygen in the deposited film(s) as compared to, for example, a fully stoichiometric metal-oxide target material that is being sputtered. One potential cause of the oxide deficiency in the deposited film(s) is that the various atomic or molecular elements of the target assembly 104 surface will be sputtered at different relative rates or yields when impacted by the incident ion beam 108. This physical phenomenon is often referred to as “differential sputtering”. Also different sputtered atomic or molecular elements will have different distribution of ejection angles off the target assembly 104 for a given incident ion beam angle. As a result, the flux of material arriving from the sputter plume 110 onto the substrate assembly 106 may not condense or deposit films with the same stoichiometric composition as the sputter target assembly 104. This variation of oxide in the ion beam, when deposited as a thin film, can contribute to optical losses in the deposited thin film, particularly in the ultra-violet range.

A hydroxide carrying compound (for example, H₂O) is provided to the enclosure 116 by a hydroxide source 120. The hydroxide carrying compound interacts with the energetic particles in the enclosure and forms hydroxide ions (OH⁻) as well as other ions. In another implementation, the hydroxide carrying compound can be introduced to the enclosure 116 through an inductively coupled plasma (IPC) source that generates hydroxide ions (i.e., OH⁻) and other ions before entering the enclosure. In addition to hydroxide ion, other ionic species, such as hydrogen (H+) and/or oxygen (O−) may be present that facilitate formation of the oxide coating. OH−, H+ and O− as used here indicate unbound radical species of hydrogen and/or oxygen. However, hydroxide ion (OH−), in general, is more reactive than hydrogen (H+) and oxygen (O−) ions. Other sources of hydroxide ion, such as H₂O₂, may be used, however these sources should be selected so that unwanted compounds are not introduced into the process chamber or else removed from (e.g., pumped out of) the chamber so that they do not take part in the chemical reaction that forms the optical film.

The hydroxide ions, whether introduced or generated, assist in the formation of the oxide coating on the substrate being coated and thus reduce the absorption loss. Without being bound by theory, the primary mechanism is thought to be to reduction of dislocations and unsatisfied chemical bonds in the coating.

The amount of hydroxide ion added by the source 120 is sufficient to maintain the hydroxide ion concentration close to or at a constant partial pressure at all time. The partial pressure of the hydroxide ion in the enclosure 116 may be, e.g., about 1×10⁻⁴ torr, or even as low as 1×10⁻⁵ torr. In some implementations, the hydroxide ion is at a partial pressure of 5×10⁻⁵ torr to 1×10⁻³ torr. When water vapor is the hydroxide source 120, the flow rate may be about 5 sccm to about 50 sccm, (e.g., 5 sccm to 30 sccm or to 15 sccm) with a particular exemplary flow rate of water vapor (e.g., DI water vapor) into the enclosure 116 of 10 sccm (standard cubic cm per minute) at room temperature; such a flow rate results in a partial pressure of about 2 orders of magnitude higher than any residual water vapor (humidity) that may be inherently present in the enclosure 116, which may be, e.g., at a pressure of about 1×10⁻⁶ torr to 1×10⁻⁷ torr.

The hydroxide source 120 may be continuously added to the enclosure 116 or may be intermittent (e.g., pulsed). Because gases are continuously being removed from the enclosure 116 by the pump(s) that maintain the enclosure 116 at vacuum, it is desired to maintain the hydroxide ion concentration close to a constant pressure at all time.

In order to counteract the depletion of oxygen in the enclosure 116 due to, e.g., the vacuum pumps and the oxide reaction, a partial pressure or added concentration of gaseous compounds may be injected into the enclosure 116. For example, a gaseous reactive oxygen carrier (e.g., O₂) may be added to the enclosure 116 via an oxygen source 122 to provide additional reactive oxygen to the plume 110 and to assist the deposition process. This may help to obviate the aforementioned deficiency or depletion of oxygen concentration in the deposited film stoichiometry when using sputter depositions systems like the ion sputter system 100. Further, the additional gaseous reactive oxygen carrier may also improve the morphologic or optical properties of the oxide-based optical films deposited on the substrate assembly 106.

Another possible cause of absorption loss may be attributed to impurities in the oxide layer. As indicated above, any source of hydroxide ion can be used, however, the source should be selected so that unwanted compounds are not introduced into the process chamber, as these unwanted compounds could undesirably react and be found in the optical film.

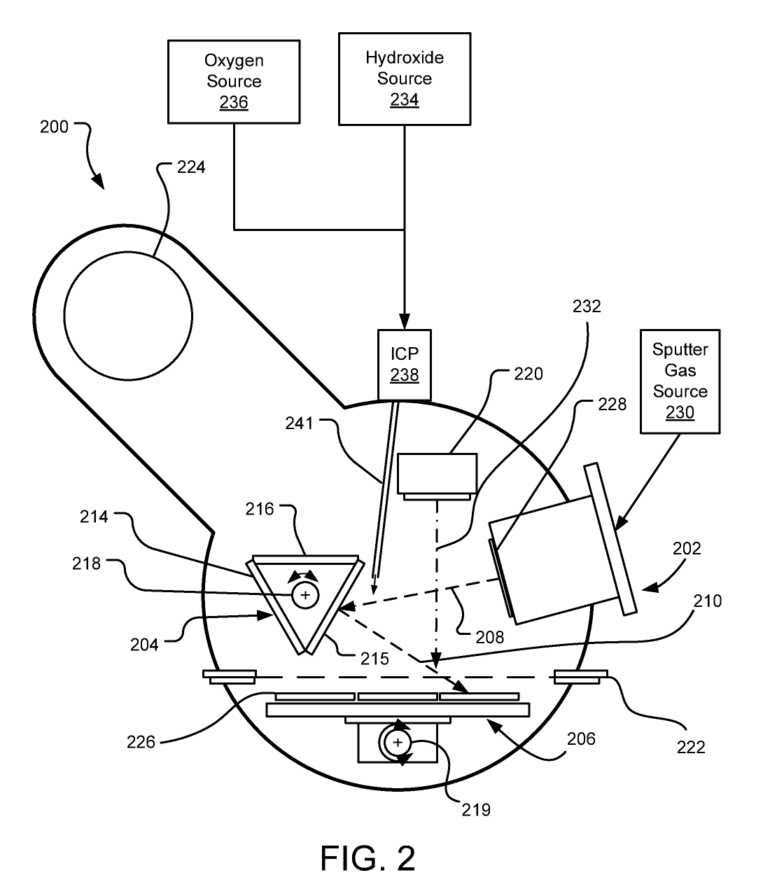

FIG. 2 illustrates an example implementation of a hydroxide assisted ion beam sputter deposition system 200. More specifically, the sputter deposition system 200 illustrated is a dual ion beam sputter deposition system. The sputter deposition system 200 includes a main radio frequency antennae (RF) ion source 202, a target assembly 204, and a substrate assembly 206. The substrate assembly 206 may be tilted about a shaft 219. The main ion source 202 generates an ion-beam 208 that passes through a grid 228 and is directed toward the target assembly 204. In one implementation, the main ion source 202 has three grids 228 (e.g., a screen grid, an accelerator grid, and a decelerator) with grid voltages ranging, e.g., between −1000V and +1500V, producing a beam current ranging, e.g., up to 1.5 A. The ion-beam 208 may have an approximately circular cross section.

Ion sputter gas (e.g., Ar, Kr, Ne, Xe, or any combination thereof) may be provided to the main ion source 202 via a sputter gas source 230. The sputter gases are ionized within the main ion source 202 to form a discharge or plasma (not shown) and the ions are then extracted from the main ion source 202 as the ion beam 208. The target assembly 204, upon interaction with the ion beam 208, generates a sputter plume 210 that deposits a desired material on one or more substrates (e.g., substrate 226) of the substrate assembly 206.

The sputter deposition system 200 may include a chamber door 222 to access the contents of the sputter deposition system 200, when open. The chamber door 222 maintains vacuum conditions in the sputter deposition system 200, when closed (as illustrated). Further, the sputter deposition system 200 may include a load-lock system that allows the substrate assembly 206 to be changed while the system 200 remains under vacuum conditions (e.g., without opening the chamber door 222).

The substrate(s) 226 may be a single or arrayed batch of substantially planar wafers or optical lenses or flats. The substrate(s) 226 may have additional 3D features, such as cubic (or faceted) optical crystals or curved optical lenses, for example. In addition, the substrate(s) 226 may be masked with mechanical templates or patterned etch resist layers (e.g., photo-resist) to help facilitate selected patterning of deposited films or ion treatment over the surface areas of the substrate(s).

The target assembly 204 includes a plurality of targets, in this implementation three targets 214, 215, 216; each of the targets 214, 215, 216 may include the same or different materials for sputtering. Other systems may include fewer or greater numbers of targets. The target assembly 204 can rotate about a shaft 218 to expose a selected target to the ion beam 208. Further, the orientation of the selected target can be varied during deposition to help distribute wear across the target, the target assembly 204 and/or the substrate assembly 206, and to improve deposition uniformity. Additionally or alternately, each of the targets 214, 215, 216 may be rotated in some implementations.

The system 200 may have an assist RF ion source 220 to assist the deposition of the sputter plume 210 on the substrate assembly 206. In one implementation of the sputter deposition system 200, a gating mechanism (not shown) is used to manage the amount and location of the deposition of the sputter plume 210 on the substrate assembly 206. In one example implementation, the assist ion source 220 generates an ion beam 232 that is directed toward the substrate assembly 206. This ion beam 232 may be used, for example, to either pre-clean or pre-heat the surface of the substrate(s). In another implementation, the assisting ion beam 232 is used in combination with the sputter plume 210 to enhance deposition performance (e.g., increase material deposition density, increase surface smoothness, etc.) on the substrate assembly 206.

An implementation of the sputter deposition system 200 is provided with a vacuum system pump and plenum 224 to generate and maintain a vacuum or near-vacuum condition inside the sputter deposition system 200.

As indicated above, hydroxide ion is provided to the evacuated sputter deposition system 200 to assist the deposition process to improve the deposition of oxide thin films on the substrate(s) 226 and reduce the optical absorption of the deposited optical film. The hydroxide source (e.g., vaporized H₂O) is added to the sputter deposition system 200 via a hydroxide source 234. In some implementations, the hydroxide source is added via a mass flow controller without actively disassociating the source, but rather, the hydroxide sources interacts with the energetic ions from the ion source 220 and/or the sputter gas source 230 to form the disassociated OH− ion.

Other reactive ions such as hydrogen (H⁺) and/or oxygen (O⁻, O⁻²), that may result from the hydroxide source may also further reduce optical absorption of the deposited optical film. In an implementation utilizing vaporized H₂O as the hydroxide source, the H₂O may be supplied using a mass flow controller (MFC) to measure the H₂O, and/or metering valves to control the flow of the H₂O vapor in the range of about, e.g., 5 sccm to about 50 sccm. In one implementation, the partial pressure of the H₂O ranges between about 5×10⁻⁵ torr to 1×10⁻³ torr.

A gaseous reactive oxygen carrier may additionally and optionally be added to the sputter deposition system 200 via a gaseous oxygen source 236 to provide additional oxygen to the sputter plume 210. In one implementation, the gaseous reactive oxygen carrier is added at a rate of about 5-50 sccm using a mass flow controller (MFC). This may help to obviate the aforementioned deficiency of oxygen concentration in the deposited film stoichiometry when using the sputter deposition system 200. Further, the additional gaseous reactive oxygen carrier may also improve the optical properties of oxide-based optical films deposited on the substrate assembly 206.

In an implementation utilizing both the oxygen carrier and the hydroxide carrier, the operating pressure of the combined carrier gas flow may range from about 0.3 mTorr to about 1.0 mTorr, for example.

The hydroxide carrier and/or the oxygen carrier gas may be introduced into the deposition system 200 directly or through a remote plasma source 238, such as an inductively coupled plasma (ICP) source.

Additionally or alternately, the hydroxide carrier and/or the oxygen carrier gas may be introduced into the deposition system 200 through a remote plasma source 238, such as an inductively coupled plasma (ICP) source, that dissociates the oxygen carrier and the hydroxide carrier into more reactive atomic or radicalized molecular constituents and/or ionized constituents (e.g., H⁺, O⁻, O⁻², OH).

In addition to the hydroxide and oxygen carrier gases discussed above, an inert gas source (not shown) may add a small amount (e.g., up to 20% of the hydroxide carrier gas volume, or, e.g., 3-5 sccm) of inert gas (e.g., Ar, Ne, He, Kr, and/or Xe) to the remote plasma source 238 in order to seed the plasma discharge and thereby make dissociation of the carrier gases more efficient. It may also make starting of the remote plasma source 238 easier and/or its operation more stable.

Further, the hydroxide and/or the oxygen carrier gas may directed toward a desired region of the sputter deposition system 200 (e.g., where the ion beam 208 impinges on the target assembly 204 or wherein the sputter plume 210 impinges on the substrate assembly 206) via a directing tube 241. The directing tube 241 may be made of any convenient material (e.g., metallic alloys or ceramics such as Al₂O₃) and have any appropriate shape and size. In other implementations, there is no directing tube 241 and the hydroxide and/or the oxygen carrier gas is distributed effectively throughout the sputter deposition system 200 without being directed to a specific location within the sputter deposition system 200. In yet a further implementation, the hydroxide and/or the oxygen carrier might be introduced into the main or secondary ion sources.

As indicated above, another possible cause of absorption loss may be attributed to impurities in the oxide layer. The source of impurities may be, for example, unwanted compounds in the hydroxide source or in the optional oxygen source that undesirably react and are found in the resulting optical film. Another potential source of impurities is any of the process equipment present within the system 209, including the grid 228 through which ions from the main ion source 202 pass in order to generate the ion-beam 208.

The grid 228 has a plurality of apertures or openings therein, to allow ions to pass there through; the spacing, shape, and alignment of the apertures can adjust the direction of the exiting ion-beam 208. Inherently some ions will impinge on the grid 228 rather than passing directly through the apertures. In one implementation, the main ion source 202 has three grids 228 (e.g., a screen grid, an accelerator grid, and a decelerator) with grid voltages ranging, e.g., between −1000V and +1500V, producing a beam current ranging, e.g., up to 1.5 A.

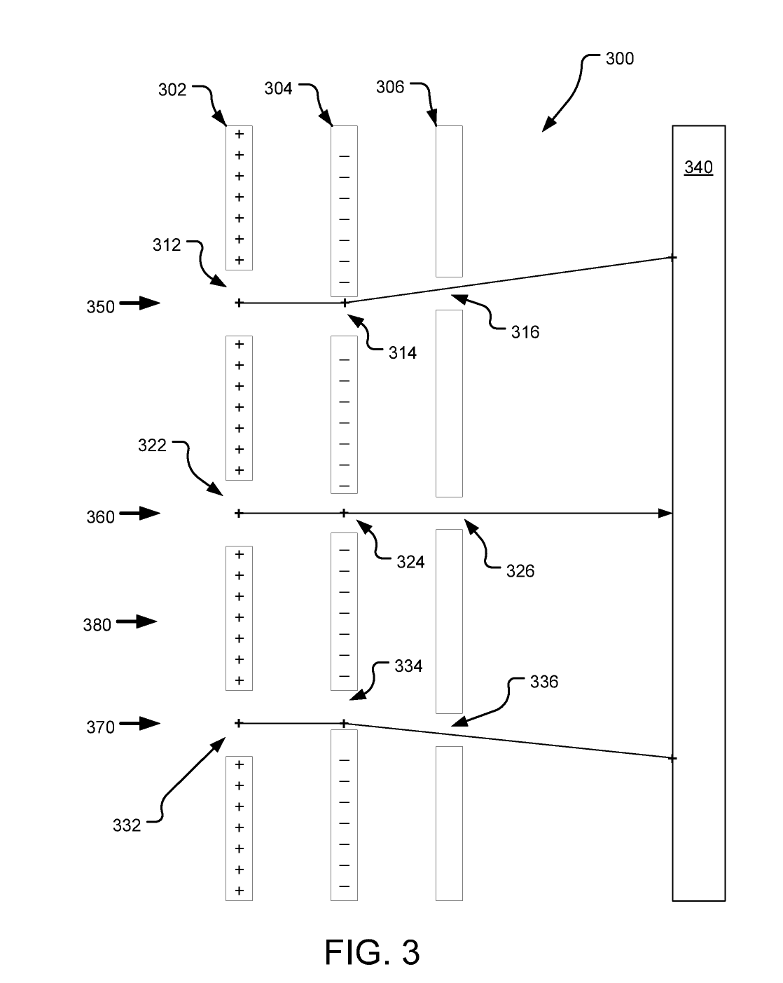

FIG. 3 illustrates an example diagram of a grid assembly 300 used in an ion beam system, such as system 200 of FIG. 2. This grid assembly 300 comprises has three grids, each having apertures there through. The grid assembly 300 has a first grid 302 also referred to as a screen grid, a second grid 304 also referred to as an acceleration grid, and a third grid 306 also referred to as a deceleration grid, shown in a side view. It should be understood that different combinations of grids may be used, including configurations having a larger number or a fewer number of grids; some implementations use only one grid. In one implementation, the grids are circular in shape, with each grid having a substantially similar diameter, although other shapes are contemplated. In another implementation, the grids may have a concave or a convex dished shape.

As shown in FIG. 3, the three grids 302, 304, and 306 are positioned parallel to one another; while the grids are shown positioned parallel to one another, this characteristic is not required. In some implementations, the grids may be slightly non-parallel with slightly varying distances across the faces of the grids.

The grids 302, 304, and 306 each have an array of corresponding holes or apertures there through, particularly, grid 302 has holes 312, 322, 332, grid 304 has holes 314, 324, 334, and grid 306 has holes 316, 326, 336. In one implementation, the grids are substantially circular in shape with a substantially circular array of holes, although other grid shapes and hole arrays are contemplated, for example rectangular and elliptical.

The grids 302, 304, 306 are positioned such that the screen grid 302 forms the downstream boundary of a discharge chamber of an ion source (e.g., ion source 202 of FIG. 2). The discharge chamber generates a plasma of positively charged ions (e.g., from a noble gas, such as argon), and the grids 302, 304, 306 extract and accelerate ions from the plasma through the grid holes toward a work piece 340 (e.g., a sputter target or substrate).

Three holes for each grid (e.g., holes 312, 322, 332 for grid 302) are shown to illustrate how ions from the ion source are organized in a collimated ion beam made up of individual beamlets, wherein a beamlet comprises ions accelerating through individual sets of corresponding holes in the grids 302, 304, and 306. In practice, individual ions of each beamlet flood generally along a center axis through a hole (e.g., hole 312) in the screen grid 302 in a distribution across the open area of the hole. The beamlet ions continue to accelerate toward the acceleration grid 304, flooding generally along a center axis through a corresponding hole 314. Thereafter, the momentum imparted by the acceleration grid 304 on the beamlet ions propels them generally along a center axis through the hole 316 in the deceleration grid 306 in a distribution across the open area of the hole and toward a downstream positioned work piece 340.

The screen grid 302 is closest to the discharge chamber and is therefore the first grid to receive the emission of ions from the discharge chamber. As such, the screen grid 302 is upstream of the acceleration grid 304 and the deceleration grid 306. The screen grid 302 comprises a plurality of holes strategically formed through the grid. All of the holes in the screen grid 302 may have the same diameter or may have varying diameters across the face of the screen grid 302. Additionally, the distance between the holes may be the same or of varying distances. The screen grid 302 is illustrated in FIG. 3 as four vertical bars in a single column separated by spaces representing the three holes 312, 322, 332 within the screen grid 302. The screen grid 302 is marked with plus (+) signs, representing the screen grid 302 as being positively charged or biased.

The acceleration grid 304 is positioned immediately downstream of the screen grid 302 in FIG. 3. As such, the acceleration grid 304 is downstream of the discharge chamber and the screen grid 302 and upstream of the deceleration grid 306. The acceleration grid 304 comprises a plurality of holes 314, 324, 334 strategically formed through the grid 304, each hole generally corresponding to a hole in the upstream screen grid 302. The acceleration grid 304 is illustrated in FIG. 3 as four vertical bars in a single column separated by spaces representing the three holes 314, 324, 334 within the acceleration grid 304. The acceleration grid 304 is marked with minus (−) signs, representing that the acceleration grid 304 as being negatively charged or biased. A negative charge or bias on the acceleration grid 304 extracts the ions from the plasma and through the holes in the screen grid 302.

The deceleration grid 306 is positioned immediately downstream of the acceleration grid 304 in FIG. 3. As such, the deceleration grid 306 is downstream of the discharge chamber, the screen grid 302 and the acceleration grid 304 and upstream of the work piece 340. The deceleration grid 306 comprises a plurality of holes 314, 324, 334 strategically formed through the grid, each hole generally corresponding to a hole in the acceleration grid 304. The deceleration grid 304 is illustrated in FIG. 3 as four vertical bars in a single column separated by spaces representing the three holes 314, 324, 334 within the deceleration grid 306. The deceleration grid 306 is typically grounded or charged with a small negative potential or bias.

Although holes (e.g., holes 312, 322, 332, 314, 324, 334, 316, 326, 336) are often formed by drilling, they may also be formed by other methods or combinations of methods including but not limited to milling, reaming, electro discharge machining (EDM), laser machining, water jet cutting and chemical etching.

In one implementation, any or all of the screen grid 302, the acceleration grid 304 and deceleration grid 306 include the same number of holes. However, additional implementations may provide for a differing number of holes between any of the grids. All of the holes 312, 322, 332, 314, 324, 334, 316, 326, 336 may have the same diameter or may have varying diameters of holes in the same grid or across the multiple grids. Additionally, the distance between the holes may be the same or of varying distances, again, in the same grid or across the multiple grids. The position of the holes, from the screen grid 302 to the acceleration grid 304 to the deceleration grid 306 may be aligned or misaligned. In some implementations, the holes are misaligned, in order to change the course of the ions as they pass through the grids.

After the ions pass through holes in the screen grid 302, the acceleration grid 304 and then the deceleration grid 306, the ions collide into the downstream positioned work piece 340, such as a sputter target or substrate. As ions collide with the surface of a target, an amount of material from the target separates from the surface of the target, traveling in a plume toward another work piece, such as a substrate to coat the surface of a substrate (not shown). With multiple targets of differing material coats, multi-layer coatings may be created onto a single substrate.

FIG. 3 shows three ions 350, 360, and 370 passing through holes in the three grids 302, 304, 306 and colliding into the surface of the work piece 340; particularly, ion 350 passes through holes 312, 314, 316, ion 360 passes through holes 322, 324, 326, and ion 370 passes through holes 332, 334, 336. However, it should be understood that the three ions 350, 360, 370 generally represent a distribution of ions flooding through the holes in the three grids 302, 304, and 306. As the ions 350, 360, 370 pass through the holes, their trajectory may be affected by the charge on grids 302, 304, 306. Without going into detail here, it is possible to have one or more grids with appropriate hole size, relative offset and voltage settings to direct the net steering angle of a beamlet.

Not all ions from the ion source (e.g., main ion source 202 of FIG. 2) pass through the grids 302, 304, 306, but rather, some ions collide with and impinge on one or more of the grids 302, 304, 306. FIG. 3 illustrates an ion 380 that is aligned to collide with the grid 302 rather than pass through either hole 322 or hole 332. The ion 380, when it collides with the screen grid 302, has a fairly low energy and in some implementations causes little or no material to separate from the surface of the grid, and thus, causes little or no contamination.

However, after passing through a hole in the screen grid 302, such as hole 312, hole 322 or hole 332, an ion, such as any one of ions 350, 360, 370, is more energized. These energized ions (e.g., ion 350, 360 or 370) are attracted to the subsequent grid 304 and may have an off-axis acceleration as they pass through the hole (e.g., hole 312, 322, 332), causing the ion (e.g., ion 350, 360, 370) to collide with the subsequent accelerator grid 304. As this energized ion collides with the grid 304, an amount of material from the grid 304 separates from the surface of the grid (just as an amount of target material separates from the surface of the target when hit by ions that do pass through the holes). The material that separates from the grid 304 results in a molecular particle, or even an atom, present in the sputter deposition system.

Similarly, after passing through a hole in the accelerator grid 304, such as hole 314, 324, 334, the ion is even more energized. These energized ions (e.g., ion 350, 360 or 370) may have an off-axis acceleration as they pass through the hole (e.g., hole 314, 324, 334) causing the ion (e.g., ion 350, 360, 370) to collide with the subsequent decelerator grid 306. As this energized ion collides with the grid 306, an amount of material from the grid 306 separates from the surface of the grid (just as an amount of target material separates from the surface of the target when hit by ions that do pass through the holes). The material that separates from the grid 306 results in a molecular particle, or even an atom, present in the sputter deposition system.

The particles from the grid(s) 304, 306 and optionally 302 may, for example, react with the hydroxide source or the oxygen source, and thus be the source of an impure oxide on the optical film, which results in absorption loss. Alternately, the particle may travel to the optical film and become an impurity in the film, which results in absorption loss, due to possibly both a chemical defect in the film and a physical defect in the film.

To inhibit the occurrence of any unwanted compound in the deposition chamber, the grid assembly 300, particularly any or all of the grids 302, 304, 306, are formed of a material that will not deleteriously affect the optical film if the material of the grid assembly 300 is found in the optical film, either as a chemical or a physical impurity. In one implementation, the grid assembly 300 (e.g., one or more of the grids 302, 304, 306) is formed from the base molecule of an oxide that is an acceptable optical film, such as Si (silicon), Al (aluminum), Hf (hafnium), Zr (zirconium), Sc (scandium), Y (yttrium), Ta (tantalum), Ti (titanium), Nb (niobium), and/or Yb (ytterbium). The grid material can be selected to be a component of the oxide optical film being deposited, although this is not a requirement. For example, an Si grid can be used when depositing an SiO₂ optical film. Similarly, for example, an Al grid can be used when depositing an Al₂O₃ optical film. Alternately, for example, a Zr grid can be used when depositing an SiO₂ optical film.

Depending on the material used for the grid assembly, the material may be drilled, chemically etched, molded, etc. to form the apertures of holes, as is most conducive for the particular material. For example, aluminum, titanium and tantalum may be conducive to drilling, due to their malleable nature, whereas silicon may be more conducive to chemical etching.

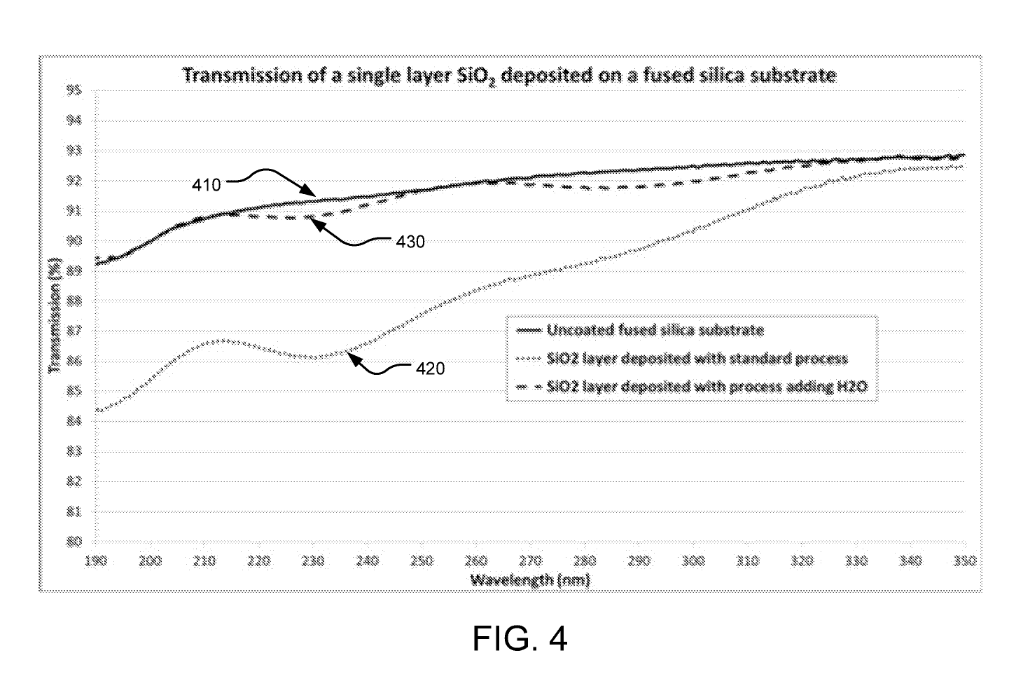

FIG. 4 illustrates an example spectral transmission scan 400 of an SiO₂ single-layer film deposited over a fused quartz (i.e., silica) substrate using a hydroxide-assisted ion beam sputter deposition system, particularly, a water vapor assisted deposition. During the deposition of the SiO₂ single-layer film, H₂O vapor flowed through an ion source at about 10 sccm. The deposited SiO₂ film thickness was about 335 nm.

Curve 410 illustrates the spectral transmission of the uncoated quartz substrate, curve 420 illustrates the SiO₂ single-layer film deposited over the quartz substrate without using hydroxide ion, and curve 430 illustrates the SiO₂ single-layer film deposited over the quartz substrate using hydroxide ion, particularly H₂O vapor, and oxygen. For an ideal SiO₂ single-layer film, the spectral transmission scan approaches that of the uncoated substrate at the interference maxima.

Curve 430 clearly illustrates that using hydroxide (e.g., H₂O vapor) additive when applying the SiO₂ film moves the spectral transmission substantially closer to the spectral transmission of the uncoated substrate as shown in curve 410, which illustrates a similar SiO₂ film applied without the hydroxide (e.g., H₂O vapor) process gas. As a result, the coating applied with the hydroxide (e.g., H₂O vapor) process gas exhibits a much lower loss condition than the curve 420, where no hydroxide (e.g., H₂O vapor) was added; this effect is more pronounced at lower wavelengths. This shows that the addition of hydroxide to the processing environment for SiO₂ single-layer film can yield an optical film with less loss than without hydroxide, which is desirable for most UV coatings.

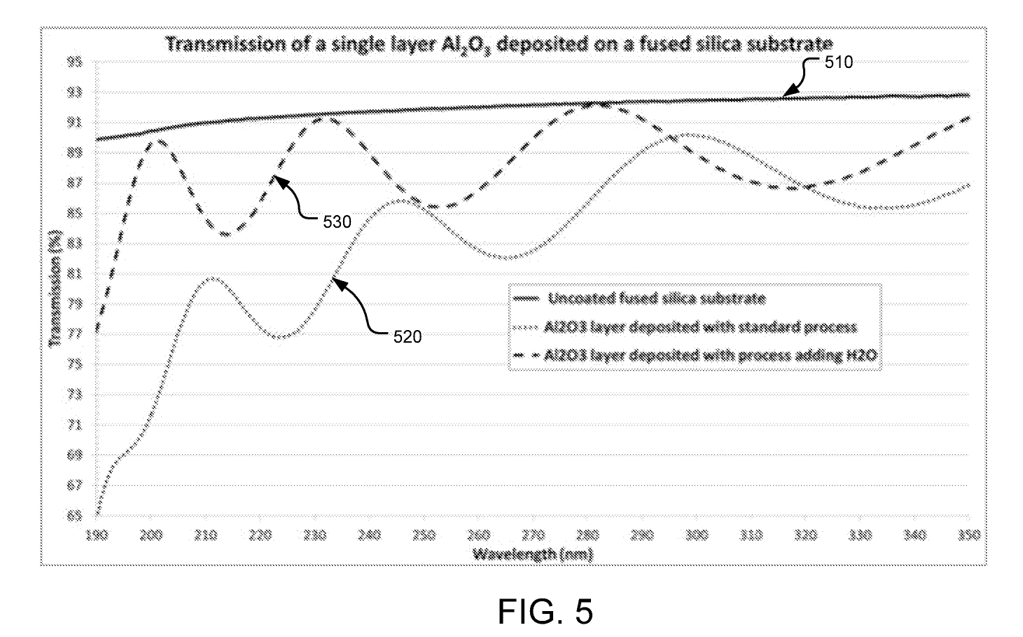

FIG. 5 illustrates an example spectral transmission scan 500 of an Al₂O₃ single-layer film deposited over a fused quartz (i.e., silica) substrate using a hydroxide-assisted ion beam sputter deposition system, particularly, a water vapor assisted deposition. During the deposition of the Al₂O₃ single-layer film, H₂O vapor flowed through an ion source at about 10 sccm. The deposited Al₂O₃ film thickness was about 330 nm.

Curve 510 illustrates the spectral transmission of the uncoated quartz substrate, curve 520 illustrates the Al₂O₃ single-layer film deposited over the quartz substrate without using hydroxide ion, and curve 530 illustrates the Al₂O₃ single-layer film deposited over the quartz substrate using hydroxide ion, particularly H₂O vapor, and oxygen.

For an ideal Al₂O₃ single-layer film, the interference maxima of the spectral transmission scan approaches that of the uncoated substrate. Curve 530 clearly illustrates that using hydroxide (e.g., H₂O vapor) additive when applying the Al₂O₃ film moves the spectral transmission substantially closer to the spectral transmission of the uncoated substrate as shown in curve 510, which illustrates a similar Al₂O₃ film applied without the hydroxide (e.g., H₂O vapor) process gas. As a result, the coating applied with the hydroxide (e.g., H₂O vapor) process gas exhibits a much lower loss condition than the curve 520, where no hydroxide (e.g., H₂O vapor) was added; this effect is more pronounced at lower wavelengths. This shows that the addition of hydroxide to the processing environment for Al₂O₃ single-layer film can yield an optical film with less loss than without hydroxide, which is desirable for most UV coatings.

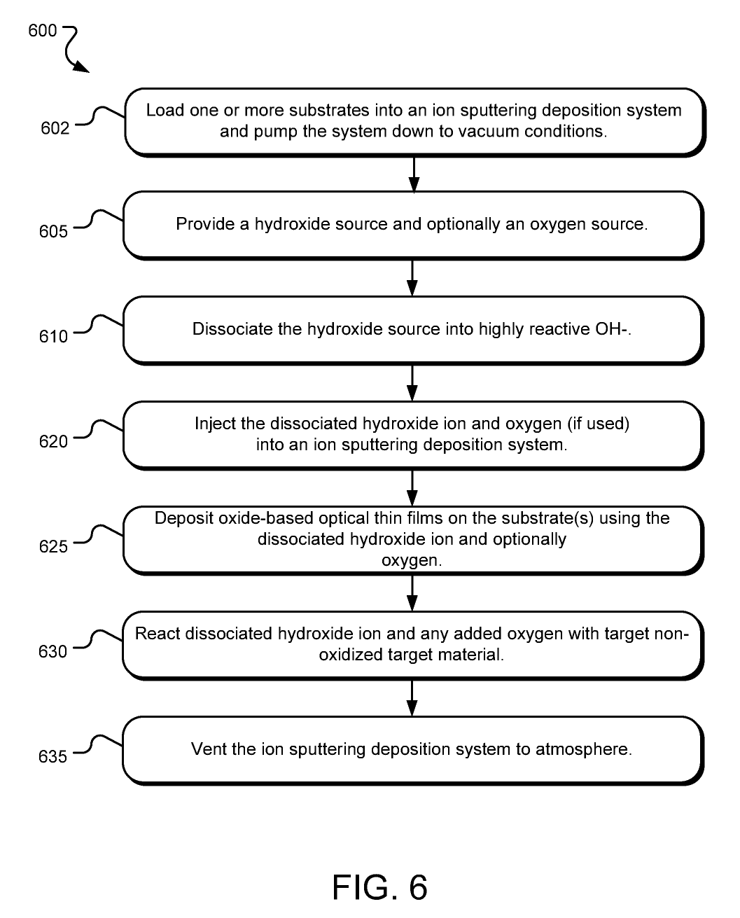

FIG. 6 illustrates an example method 600 for assisting the deposition of oxide-based optical thin films using hydroxide ion and optionally oxygen. A loading operation 602 loads one or more substrates (e.g., quartz or silica) into an ion sputtering deposition system and pumps the system down to vacuum (or near vacuum) conditions. A providing operation 605 provides a hydroxide ion source and optionally an oxygen source. The hydroxide source may be a gaseous carrier (e.g., H₂O vapor, H₂O₂). The oxygen source may be O₂.

A dissociating operation 610 dissociates the hydroxide ion (OH⁻) in the provided source into highly reactive molecules. In some implementations, the dissociating operation 610 also dissociates the oxygen (O⁻², O⁻) in the provided oxygen source into highly reactive atoms or molecules. In one implementation, the dissociating operation 610 is accomplished using a remote ICP source.

An injecting operation 620 injects the dissociated hydroxide and oxygen into an ion sputtering deposition system. The hydroxide and oxygen is introduced into the system under vacuum (or near vacuum). The ion sputtering deposition system focuses an ion beam on a metal-oxide compound target. The ion beam sputters a plume of metal-oxide material from the target and directs it toward a substrate. The plume of metal-oxide material is used to create oxide-based optical films (e.g., SiO₂, Al₂O₃, HfO₂, ZrO₂, Sc₂O₃, Y₂O₃, Ta₂O₅, TiO₂, Nb₂O₅, Yb₂O₃) on the substrate.

An assisting operation 625 assists the deposition of the oxide-based optical films on the substrate(s) with the dissociated hydroxide and oxygen. The dissociated hydroxide provides additional highly reactive oxygen to the ion sputtering deposition system, which may help to obviate any deficiency of oxide concentration in the deposited film stoichiometry.

In one example implementation, a single layer oxide-based thin film with low losses in the 150-350 nm UV wavelength spectral line range is produced using method 600. In various implementations, the aforementioned transmission efficiency may be accomplished before or after UV curing the oxide-based thin films.

A reacting operation 630 reacts dissociated hydroxide ion and any oxygen with the non-oxidized target material, thus fully oxidizing the deposited thin film material.

An optional venting operation 635 vents the ion sputtering deposition system to atmosphere. The venting operation 635 enables the substrate with the oxide-based optical film(s) to be removed from the ion sputtering deposition system and/or a new substrate to be inserted into the ion sputtering deposition system.

The logical operations may be performed in any order, adding or omitting operations as desired, unless explicitly claimed otherwise or a specific order is inherently necessitated by the claim language. The above specification, examples, and data provide a complete description of the structure and use of exemplary embodiments of the invention. Since many embodiments of the invention can be made without departing from the spirit and scope of the invention, the invention resides in the claims hereinafter appended. Furthermore, structural features of the different embodiments may be combined in yet another embodiment without departing from the recited claims.

1. A method comprising:
depositing an ion beam sputtered metal oxide coating on a substrate in the presence of dissociated hydroxide ion.

2. The method of claim 1, further comprising:
depositing the metal oxide coating in the presence of oxygen.

3. The method of claim 1, comprising:
providing water vapor to form the dissociated hydroxide ion.

4. The method of claim 3, comprising:
providing 5 to 50 sccm water vapor.

5. The method of claim 4, comprising:
providing 5 to 15 sccm water vapor.

6. The method of claim 3, comprising:
providing water vapor at a partial pressure of 5×10⁻⁵ torr to 1×10⁻³ torr.

7. The method of claim 1, further comprising:
sputtering metal oxide material from a target onto the substrate using an ion beam.

8. The method of claim 7, wherein the target comprises the metal oxide.

9. The method of claim 7, wherein the target comprises a metal and the metal oxide.

10. The method of claim 1, wherein the metal oxide coating is an optical coating.

11. The method of claim 1, wherein the metal oxide coating comprises at least one of SiO₂, Al₂O₃, HfO₂, ZrO₂, Sc₂O₃, Y₂O₃, Ta₂O₅, TiO₂, Nb₂O₅, Yb₂O₃.

12. A method of forming an optical coating, the method comprising:
depositing a metal oxide coating on a substrate in the presence of dissociated hydroxide ion.

13. The method of claim 12, wherein the deposition is performed by a sputtering process.

14. The method of claim 12, wherein the metal oxide coating comprises at least one of SiO₂, Al₂O₃, HfO₂, ZrO₂, Sc₂O₃, Y₂O₃, Ta₂O₅, TiO₂, Nb₂O₅, Yb₂O₃.

15. The method of claim 12, comprising:
providing water vapor to form the dissociated hydroxide ion.

16. The method of claim 15, comprising:
providing 5 to 50 sccm water vapor.

17. The method of claim 16, comprising:
providing 5 to 15 sccm water vapor.

18. The method of claim 12, comprising:
providing water vapor at a partial pressure of 5×10⁻⁵ torr to 1×10⁻³ torr.

19. The method of claim 12, further comprising:
depositing the metal oxide coating in the presence of oxygen.

20. A method of lowering the absorption losses of optical coatings at wavelengths shorter than 350 nm, the method comprising:
introducing a hydroxide ion (OH−) source either H₂O, H₂O₂ or the disassociated components H⁺, O²⁻, and Off as part of the process gasses during the deposition process.

21. The method of claim 21 wherein introducing the hydroxide ion source also comprises introducing the disassociated components H⁺, O⁻², and/or O⁻.
